(19) United States
(12) Patent Application Publication
(10) Pub. No.: US 2008/0204089 A1
(43) Pub. Date: Aug. 28, 2008

(54) Dynamic frequency dividing circuit operating within limited frequency range

(75) Inventor: Yasuhiro Nakasha, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED

(21) Appl. No.: 11/987,702

(22) Filed: Dec. 4, 2007

(30) Foreign Application Priority Data
Feb. 22, 2007 (JP) 2007-042262

(51) Int. Cl. H03B 19/14

(52) U.S. Cl. 327/118

(57) ABSTRACT

A frequency dividing circuit has a master circuit and a slave circuit, and a load section in at least either one of the master and slave circuits is constructed to provide an impedance that decreases with increasing frequency.

### CROSS REFERENCE TO RELATED APPLICATION

This application is based upon and claims the benefit of priority from the prior Japanese Patent Application No. 2007-042262, filed on Feb. 22, 2007, the entire contents of which are incorporated herein by reference.

### BACKGROUND

The embodiments relate to a dynamic frequency dividing circuit that operates within a limited frequency range, and more particularly to a master-slave frequency dividing circuit having a master circuit and a slave circuit.

The frequency dividing circuit (frequency divider) is a basic circuit used to generate a signal whose frequency is an integral submultiple of the input signal frequency, and is widely used in a prescaler section of a frequency synthesizer IC for a radio communication system, in a clock generating section of an optical communication IC, or in a π/2 phase shifter or the like.

There are two main types of frequency dividing circuit: a static frequency dividing circuit which operates over a frequency range from near DC to high frequencies, and a dynamic frequency dividing circuit which operates within a limited frequency range. Compared with the static frequency dividing circuit, the dynamic frequency dividing circuit has the advantages of low power consumption and high operating speed, and is finding widespread use in radio/optical communication systems whose transmission speeds have been increasing in recent years.

In the prior art, Japanese Patent No. 3350337 discloses a master-slave type (also called a clocked inverter type) dynamic frequency dividing circuit having a master circuit and a slave circuit. In this prior art master-slave dynamic frequency dividing circuit, the output of the slave circuit is fed back to the master circuit, and the frequency dividing operation is performed by switching the master circuit or the slave circuit from ON to OFF or OFF to ON in accordance with an applied clock signal.

On the other hand, Japanese Unexamined Patent Publication (Kokai) No. 2000-022521 discloses a configuration in which a positive feedback circuit is incorporated in a dynamic frequency dividing circuit. The dynamic frequency dividing circuit incorporating the positive feedback circuit can extend the operating frequency range, but the power consumption increases because of the need to supply a current to the positive feedback circuit.

Further, Japanese Unexamined Patent Publication (Kokai) No. 2000-261311 (see, for example, FIG. 2) discloses a master-slave dynamic frequency dividing circuit in which the load resistance is digitally switched between different values in accordance with the operating frequency. Since this configuration requires the provision of a switching circuit and control circuit for switching the load resistance, not only the power consumption but the circuit size also increases.

### SUMMARY OF THE EMBODIMENTS

An embodiment provides a frequency dividing circuit having a master circuit and a slave circuit, wherein a load section in at least either one of the master and slave circuits is constructed to provide an impedance that decreases with increasing frequency.

### BRIEF DESCRIPTION OF THE DRAWINGS

The features and advantages of the embodiments will be more clearly understood from the following description with reference to the accompanying drawings, wherein:

FIG. 1 is a circuit diagram showing one example of a prior art master-slave dynamic frequency dividing circuit;

FIGS. 2A and 2B are diagrams for explaining the operation of the frequency dividing circuit shown in FIG. 1;

FIG. 3 is a circuit diagram showing another example of the prior art master-slave dynamic frequency dividing circuit;

FIG. 4 is a diagram showing the relationship between input sensitivity and frequency for the frequency dividing circuit shown in FIG. 3;

FIG. 5 is a circuit diagram showing a frequency dividing circuit according to a first embodiment;

FIG. 6 is a diagram showing the relationship between load resistance and frequency for the frequency dividing circuit shown in FIG. 5;

FIG. 7 is a diagram showing the relationship between input sensitivity and frequency for the frequency dividing circuit shown in FIG. 5 for comparison with the prior art frequency dividing circuit;

FIG. 8 is a circuit diagram showing a frequency dividing circuit according to a second embodiment;

FIG. 9 is a circuit diagram showing a frequency dividing circuit according to a third embodiment;

FIG. 10 is a circuit diagram showing a frequency dividing circuit according to a fourth embodiment;

FIG. 11 is a circuit diagram showing a frequency dividing circuit according to a fifth embodiment;

FIG. 12 is a circuit diagram showing a frequency dividing circuit according to a sixth embodiment; and

FIG. 13 is a circuit diagram showing a frequency dividing circuit according to a seventh embodiment.

### DETAILED DESCRIPTION OF THE EMBODIMENTS

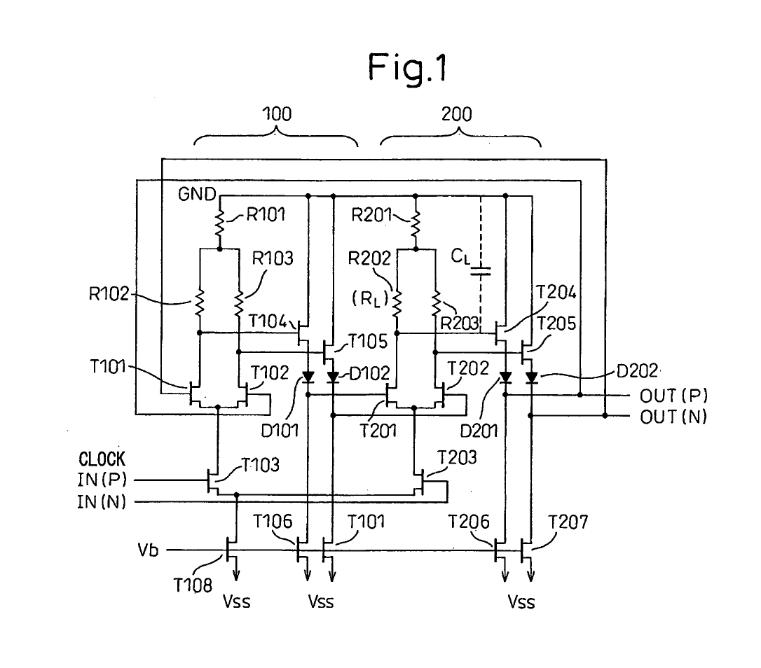

Before describing the embodiments in detail, examples of a prior art master-slave dynamic frequency dividing circuits and their associated problems will be described with reference to FIGS. 1 to 4.

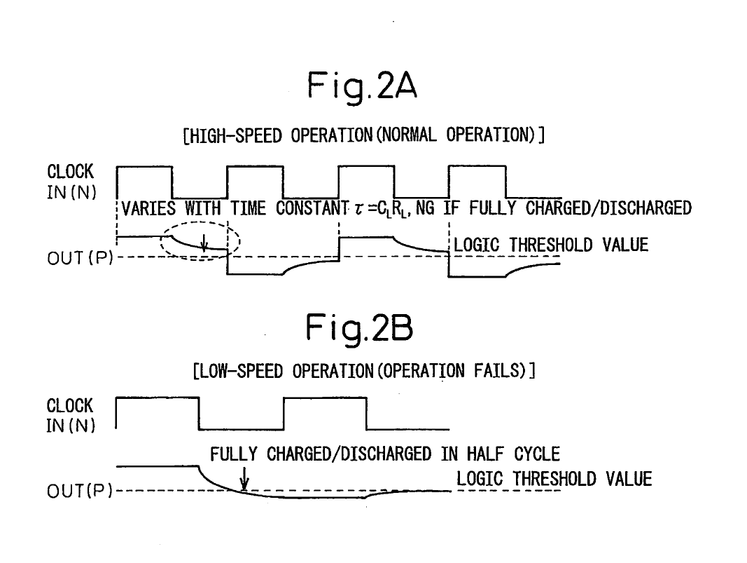

FIG. 1 is a circuit diagram showing one example of the prior art master-slave dynamic frequency dividing circuit, and FIGS. 2A and 2B are diagrams for explaining the operation of the frequency dividing circuit shown in FIG. 1. In FIG. 1, reference numeral 100 is a master circuit, 200 is a slave circuit, GND is a high potential power supply (ground potential, for example, 0 volt), Vss is a low potential power supply (for example, −1.6 volts), C_{L} is a load capacitance for the slave circuit, R_{L} is a load resistance for the slave circuit, and Vb is a control bias voltage. FIG. 2A shows the case of high-speed operation (the circuit operates normally), and FIG. 2B shows the case of low-speed operation (the circuit fails to operate normally).

As shown in FIG. 1, one example of the prior art master-slave dynamic frequency dividing circuit comprises the master circuit 100 and the slave circuit 200; here, the master circuit 100 comprises resistors R101 to R103, diodes D101 and D102, and transistors (n-channel MOS transistors) T101 to T107 (T108), and the slave circuit 200 comprises resistors R201 to R203, diodes D201 and D202, and transistors T201 to T207. The circuit shown in FIG. 1 is a differential frequency dividing circuit driven with a negative supply voltage (Vss), but the description given herein also applies to the case of a differential frequency dividing circuit driven with a positive supply voltage or a single-ended frequency dividing circuit.

Here, differential clocks IN(P) and IN(N) are applied to the gates of the transistors T103 and T203, respectively, and the differential outputs of the slave circuit 200 (the outputs OUT(P) and OUT(N) of the frequency dividing circuit) are applied to the gates of the differential pair transistors T101 and T102 in the master circuit 100, while the differential outputs of the master circuit 100 are applied to the gates of the differential pair transistors T201 and T202 in the slave circuit 200. The control bias voltage Vb is applied to the gates of the transistors T106 to T108, T206, and T207.

First, as shown in FIG. 2A, in the master-slave dynamic frequency dividing circuit, when the logic level of the clock (negative-logic clock IN(N)) is high “H” and the slave circuit 200 is ON, for example, the output of the master circuit 100 is supplied to the slave circuit 200, and a signal proportional to the amplification factor of the slave circuit 200, if it is assumed to be an amplifier, appears at the slave output (in FIG. 1, the positive-logic slave output OUT(P)).

Next, as shown in FIG. 2B, in the master-slave dynamic frequency dividing circuit, when the logic level of the clock (negative-logic clock IN(N)) goes low “L” and the slave circuit is turned off, for example, the output (positive-logic slave output OUT(P)) of the slave circuit 200 decays with the time constant R_{L}C_{L}. The negative-logic slave output OUT(N) likewise decays with the time constant R_{L}C_{L}, and the output of the master circuit 100 also decays in a similar way.

In the master-slave dynamic frequency dividing circuit, since the output signal decays with the time constant R_{L}C_{L}, as described above, the following situation occurs: that is, when the clock frequency is high, as shown in FIG. 2A, the next low to high transition of the clock (negative-logic clock IN(N)) occurs before the output signal fully decays (is fully discharged), and the circuit thus performs the frequency dividing operation normally, but when the clock frequency is low, as shown in FIG. 2B, the output signal fully decays (is fully discharged) by the time the next low to high transition of the clock (negative-logic clock IN(N)) occurs, and the circuit thus fails to perform the frequency dividing operation normally.

In this way, while the dynamic frequency dividing circuit has the advantages of low power consumption and high operating speed, since its state is determined by the charging and discharging of the load capacitance, etc., it involves the problem that the operating frequency is limited by the capacitance value and the charge/discharge performance of the circuit and, therefore, the operating frequency range is generally narrow.

On the other hand, in the case of the static frequency dividing circuit, as earlier described, if the clock changes, the original potential is retained, for example, by means of a positive feedback circuit. That is, in the static frequency dividing circuit, stable operation is achieved using the positive feedback circuit, but there arises the problem that the power consumption and the chip area increase.

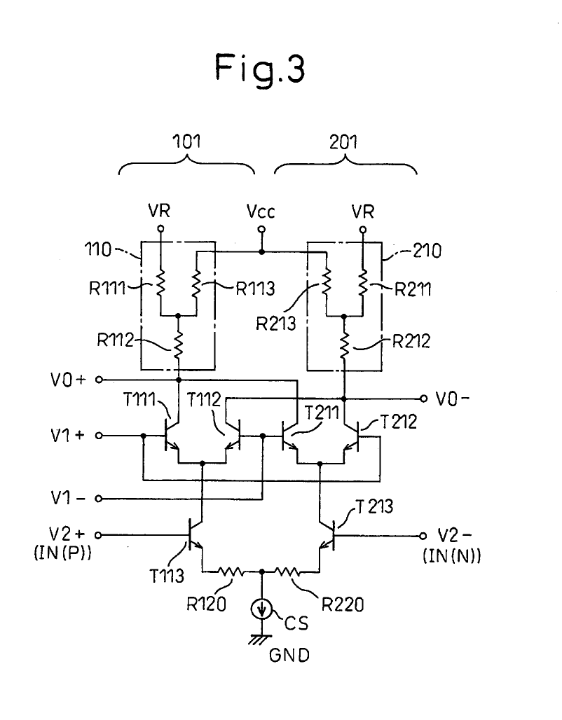

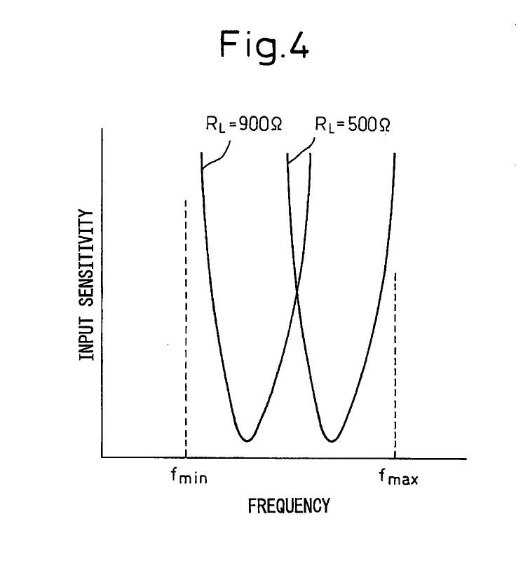

FIG. 3 is a circuit diagram showing another example of the prior art master-slave dynamic frequency dividing circuit, and FIG. 4 is a diagram showing the relationship between the input sensitivity and the frequency for the frequency dividing circuit shown in FIG. 3. The circuit shown in FIG. 3 is one disclosed in the earlier cited Japanese Unexamined Patent Publication No. 2000-261311, that is, a differential frequency dividing circuit driven with a positive supply voltage (Vcc), and uses NPN bipolar transistors as the transistors.

As shown in FIG. 3, another example of the prior art master-slave dynamic frequency dividing circuit comprises a master circuit 101 and a slave circuit 201; here, the master circuit 101 comprises resistors R111 to R113 and R120 and transistors (NPN bipolar transistors) T111 to T113, and the slave circuit 201 comprises resistors R211 to R213 and R220 and transistors T211 to T213. Reference sign CS indicates a current source.

The resistors R111 to R113 together form a load means 111 in the master circuit 101, and likewise, the resistors R211 to R213 together form a load means 211 in the slave circuit 201. Here, the load means 111 and 211 of the master circuit 101 and slave circuit 201 are each configured to be able to switch the magnitude of the load between different values.

More specifically, in the load means 111 of the master circuit 101 (the load means 211 of the slave circuit 201), when the terminal VR is left open, the load between the power supply line (Vcc) and the output terminal V0+ (V0−) is formed by the combined resistance (for example, the load resistance R_{L}=900Ω) of the resistors R112 and R113 (the resistors R212 and R213), thereby increasing the voltage amplitude so as to be able to handle a low operating frequency, and when the terminal VR is connected to the power supply line (Vcc), the load between the power supply line (Vcc) and the output terminal V0+ (V0−) is formed by the combined resistance (for example, the load resistance R_{L}=500Ω) of the resistors R111 to R113 (the resistors R222 to R213), thereby decreasing the voltage amplitude so as to be able to handle a high operating frequency.

That is, as shown in FIG. 4, the example of the prior art master-slave dynamic frequency dividing circuit shown in FIG. 3 is configured so that when the load resistance R_{L} provided by the load means 111 (211) is 500Ω, for example, an input signal (V2+, V2−) falling within a range of 40 GHz to 60 GHz is frequency-divided and, when the load resistance R_{L} provided by the load means 111 (211) is 900Ω, for example, an input signal falling within a range of 30 GHz to 50 GHz is frequency-divided; that is, by controlling the load means 111 (211) in this manner, the frequency dividing circuit can perform the frequency dividing operation over a wide frequency range of 30 GHz to 60 GHz.

As described above, it is known in the prior art to provide a dynamic frequency dividing circuit that extends the operating frequency range by switching the load resistance between different values. However, this dynamic frequency dividing circuit requires the provision of a switching circuit and control circuit for switching the load resistance, and therefore has the problem that not only the power consumption but the circuit size also increases.

An object of the embodiments is to provide a frequency dividing circuit that has a wide operating frequency range, and that achieves compact size and low power consumption by eliminating the need for a special switching circuit or control circuit.

Below, embodiments of a frequency dividing circuit will be described in detail below with reference to the accompanying drawings.

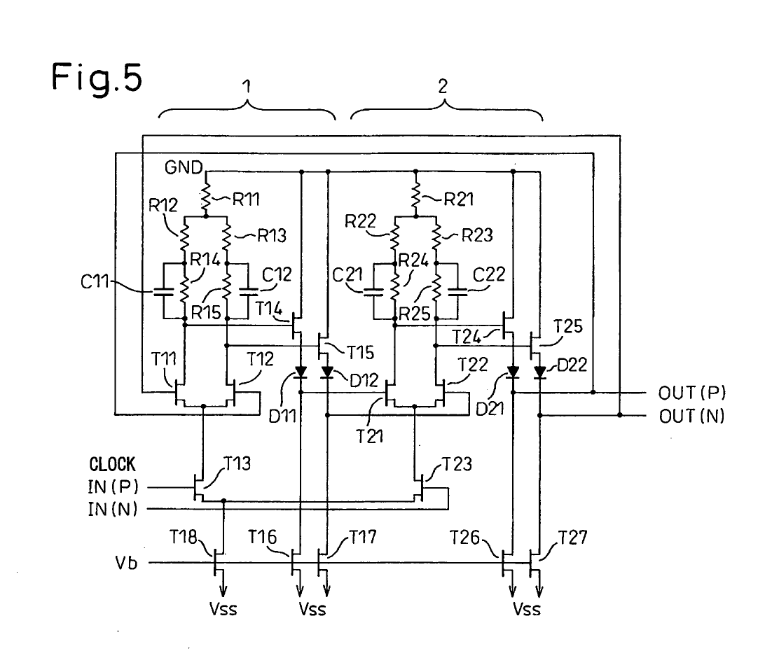

FIG. 5 is a circuit diagram showing a frequency dividing circuit according to a first embodiment. In FIG. 5, reference numeral 1 is a master circuit, 2 is a slave circuit, GND is a high potential power supply (ground potential, for example, 0 volt), Vss is a low potential power supply (for example, −1.6 volts), and Vb is a control bias voltage.

As shown in FIG. 5, the frequency dividing circuit of the first embodiment comprises the master circuit 1 and slave circuit 2; here, the master circuit 1 comprises resistors R11 to R15, diodes D1 and D2, capacitors C11 and C12, and transistors (n-channel MOS transistors) T11 to T17 (T18), and the slave circuit 2 comprises resistors R21 to R25, diodes D21 and D22, and transistors T21 to T27. The circuit shown in FIG. 5 is a differential frequency dividing circuit driven with a negative supply voltage (Vss), but the description given herein also applies to the case of a differential frequency dividing circuit driven with a positive supply voltage or a single-ended frequency dividing circuit.

As is apparent from a comparison with the prior art frequency dividing circuit previously shown in FIG. 1, in the master circuit 1 of the frequency dividing circuit of the first embodiment, the resistor R14 and capacitor C11 connected in parallel are inserted between the resistor R12 and the drain of the transistor T11, and the resistor R15 and capacitor C12 connected in parallel are inserted between the resistor R13 and the drain of the transistor T12.

Further, in the slave circuit 2 of the frequency dividing circuit of the first embodiment, the resistor R24 and capacitor C21 connected in parallel are inserted between the resistor R22 and the drain of the transistor T21, and the resistor R25 and capacitor C22 connected in parallel are inserted between the resistor R23 and the drain of the transistor T22. Here, the resistance values of the resistors R12, R13, R22, and R23 are chosen to be the same as or slightly lower than the resistance values of the corresponding resistors R102, R103, R202, and R203 in the frequency dividing circuit previously shown in FIG. 1.

In the master circuit 1, the two master-circuit load resistors R12 and R14 connected in series between the first transistor T11 of the differential transistor pair and the first power supply line (ground line GND) and the master-circuit load capacitor C11 connected in parallel with one of the two master-circuit load resistors, i.e., the resistor R14, together form a first master-circuit load section between the first transistor T11 and the first power supply line GND, while the two master-circuit load resistors R13 and R15 connected in series between the second transistor T12 of the differential transistor pair and the first power supply line GND and the master-circuit load capacitor C12 connected in parallel with one of the two master-circuit load resistors, i.e., the resistor R15, together form a second master-circuit load section between the second transistor T12 and the first power supply line GND.

Likewise, in the slave circuit 2, the two slave-circuit load resistors R22 and R24 connected in series between the third transistor T21 of the differential transistor pair and the first power supply line GND and the slave-circuit load capacitor C21 connected in parallel with one of the two master-circuit load resistors, i.e., the resistor R24, together form a first slave-circuit load section between the third transistor T21 and the first power supply line GND, while the two slave-circuit load resistors R23 and R25 connected in series between the fourth transistor T22 of the differential transistor pair and the first power supply line GND and the master-circuit load capacitor C22 connected in parallel with one of the two master-circuit load resistors, i.e., the resistor R25, together form a second slave-circuit load section between the fourth transistor T22 and the first power supply line GND.

Further, as in the frequency dividing circuit previously shown in FIG. 1, differential clocks IN(P) and IN(N) are applied to the gates of the transistors T13 and T23, respectively, and the differential outputs of the slave circuit 2 (the outputs OUT(P) and OUT(N) of the frequency dividing circuit) are applied to the gates of the differential pair transistors T11 and T12 in the master circuit 1, while the differential outputs of the master circuit 1 are applied to the gates of the differential pair transistors T21 and T22 in the slave circuit 2. The control bias voltage Vb is applied to the gates of the transistors T16 to T18, T26, and T27. Here, it will be appreciated that, in the first master-circuit load section (and similarly in the other load sections), the resistor R12 and the parallel circuit of the resistor R14 and capacitor C11 may be interchanged with each other.

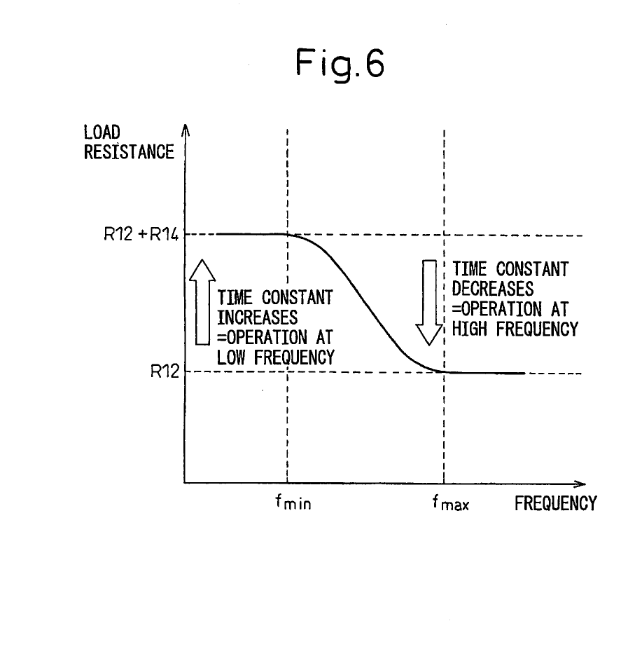

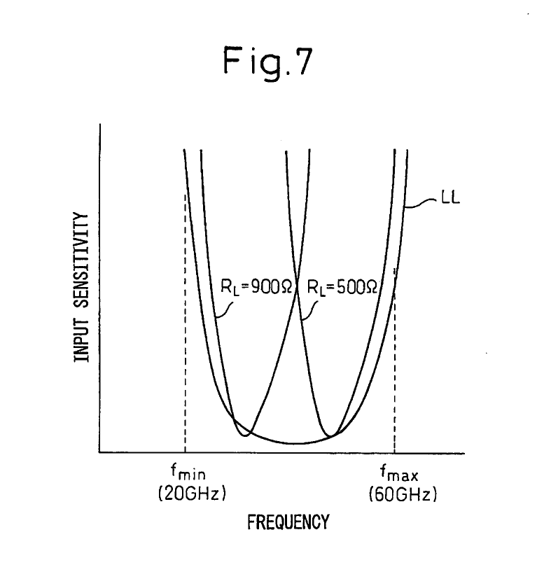

FIG. 6 is a diagram showing the relationship between the load resistance and the frequency for the frequency dividing circuit shown in FIG. 5, and FIG. 7 is a diagram showing the relationship between the input sensitivity and the frequency for the frequency dividing circuit shown in FIG. 5 for comparison with the prior art frequency dividing circuit.

As shown in FIG. 6, according to the frequency dividing circuit of the first embodiment, in the high frequency range the capacitor C11 (C12, C21, C22) short-circuits the resistor R14 (R15, R24, R25) and thus produces the same effect as if the load were formed only by the resistor R12 (R13, R22, R23). On the other hand, in the low frequency range, the impedance of the capacitor C11 (C12, C21, C22) increases so that the load is formed by the combined resistance (R12+R14) of the resistor R12 (R13, R22, R23) and the resistor R14 (R15, R24, R25).

Here, since the load capacitances in the master and slave circuits respectively can be considered substantially constant, the frequency dividing circuit of the first embodiment with the above load configuration extends the operating frequency range by reducing the time constant in the high frequency range and by increasing the time constant with decreasing frequency and thereby increasing the charge/discharge time in the low frequency range and thus reducing the signal potential change when a transition is made to a clock off state.

That is, as shown in FIG. 7, the frequency dividing circuit of the first embodiment can switch the load value between that for the high frequency range and that for the low frequency range in accordance with the operating frequency without having to use a switching circuit such as incorporated in the prior art frequency dividing circuit previously shown in FIG. 3, and can extend the operating frequency range while achieving compact size and low power consumption by eliminating the need for a special switching circuit or control circuit.

The load configuration employed in the frequency dividing circuit of the first embodiment is not conceivable by the analog circuit design concept used for conventional amplifiers, etc. The reason is that the method that connects a capacitor in parallel with the load resistor leads to an increase in gain in the low frequency range, that is, 3 dB bandwidth reduction, and the concept is thus quite contrary to the analog design concept that aims at increasing the bandwidth.

More specifically, as shown in FIG. 7, while, in the prior art dynamic frequency dividing circuit described with reference to FIGS. 3 and 4, the value of the load resistance R_{L} was switched, for example, between 900Ω and 500Ω so that the circuit was operated in the frequency range of 40 GHz to 60 GHz when R_{L}=500Ω and in the frequency range of 30 GHz to 50 GHz when R_{L}=900Ω, in the frequency dividing circuit of the first embodiment a frequency range of 20 GHz to 60 GHz is achieved (see curve LL in FIG. 7) by setting the resistors R12 (R13, R22, R23) and R14 (R15, R24, R25) and the capacitor C11 (C12, C21, C22), for example, to R12=500Ω, R14=400Ω, and C11=50 fF, respectively.

As a result, according to the frequency dividing circuit of the first embodiment, the operating frequency range can be extended by more than 30% without using a special switching circuit or control circuit. Furthermore, since the frequency dividing circuit of the first embodiment does not require the provision of a special switching circuit or control circuit, the circuit size can be reduced, and since there is no need to provide a circuit such as a positive feedback circuit that consumes extra power, the operating frequency range can be made wider than in the prior art circuit while reducing the power consumption.

The transistors used here are each constructed, for example, from an InP (Indium Phosphide) HEMT (High Electron Mobility Transistor). Since fT which is a measure of the high-frequency characteristic of this transistor exceeds 170 GHz, the frequency dividing operation is possible up to about 60 GHz. Of course, the transistors used and the values of the resistors and capacitors can be changed variously.

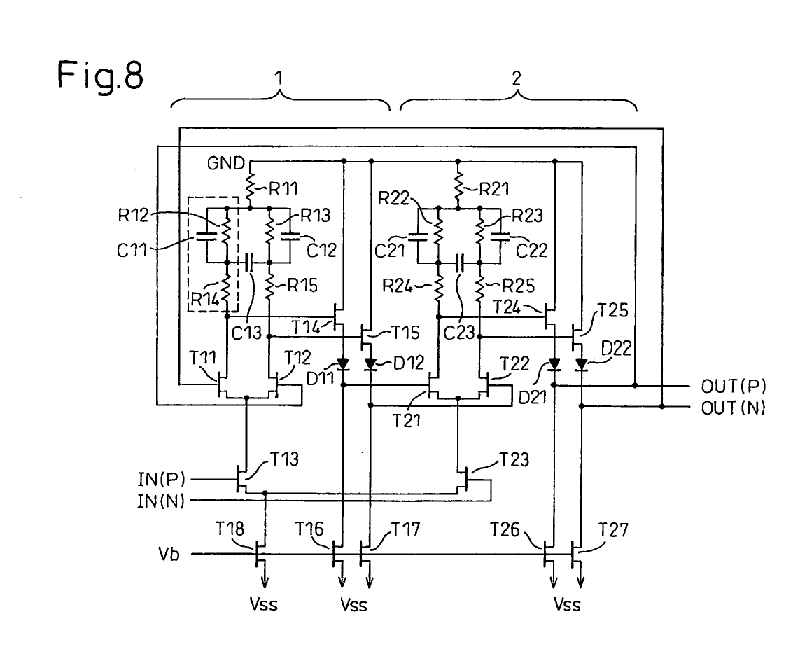

FIG. 8 is a circuit diagram showing a frequency dividing circuit according to a second embodiment.

As is apparent from a comparison between FIG. 8 and the previously shown FIG. 5, the frequency dividing circuit of the second embodiment differs from the frequency dividing circuit of the first embodiment by the addition of capacitors C13 and C23.

That is, the additional load capacitor C13 for the master circuit is provided between the node connecting the two master-circuit load resistors R12 and R14 in the first master-circuit load section and the node connecting the two master-circuit load resistors R13 and R15 in the second master-circuit load section, while the additional load capacitor C23 for the slave circuit is provided between the node connecting the two slave-circuit load resistors R22 and R24 in the first slave-circuit load section and the node connecting the two slave-circuit load resistors R23 and R25 in the second slave-circuit load section.

These additional capacitors C13 and C23 need only have half the capacitance because of the differential operation, and thus the area occupied by the circuit can be further reduced.

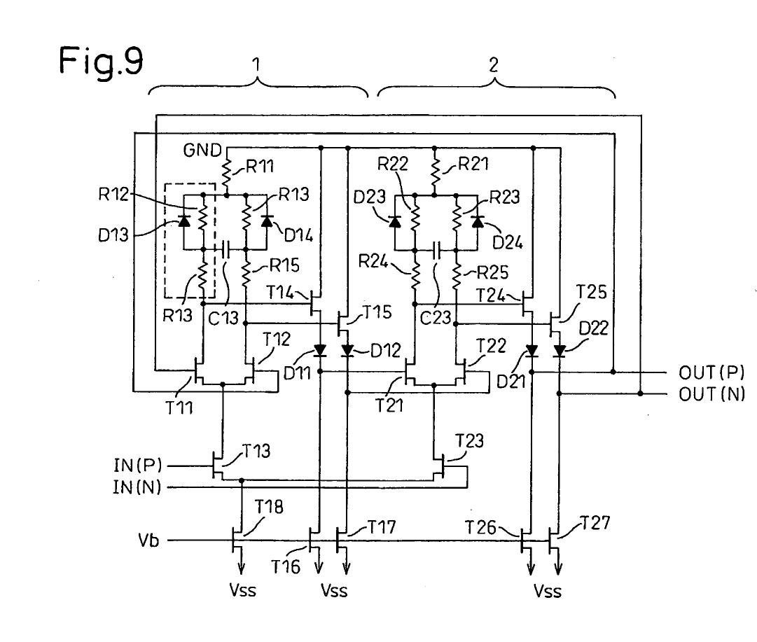

FIG. 9 is a circuit diagram showing a frequency dividing circuit according to a third embodiment.

As is apparent from a comparison between FIG. 9 and the above described FIG. 8, the frequency dividing circuit of the third embodiment differs from the frequency dividing circuit of the second embodiment in that the capacitors C11, C12, C21, and C22 are replaced by diodes D13, D14, D23, and D24, respectively, and the circuit is configured to utilize the diffusion capacitances of the diodes. That is, the diodes function as capacitors in the high operating frequency range of the frequency dividing circuit and as high-resistance elements in the low operating frequency range.

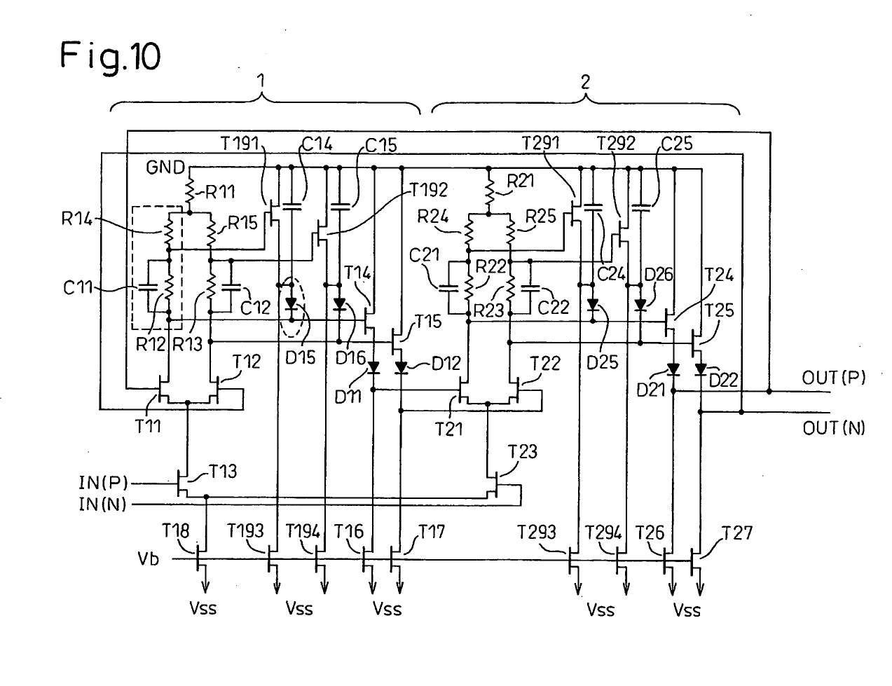

FIG. 10 is a circuit diagram showing a frequency dividing circuit according to a fourth embodiment.

As is apparent from a comparison between FIG. 10 and the previously shown FIG. 5, the frequency dividing circuit of the fourth embodiment differs from the frequency dividing circuit of the first embodiment by the addition of transistors T191 to T194 and T291 to T294, capacitors C14, C15, C24, and C25, and diodes (varactors) D15, D16, D25, and D26.

In the frequency dividing circuit of the fourth embodiment, the resistor R12 (R13, R22, R23) and the parallel circuit of the resistor R14 (R14, R24, R25) and capacitor C11 (C12, C21, C22) in FIG. 5 are interchanged with each other.

More specifically, as shown in FIG. 10, in the frequency dividing circuit of the fourth embodiment, the potential developed across the resistor R14 (R14, R24, R25) is received by the source follower circuit formed from the transistor T191 (T192, T291, T292), and the source follower output is applied to the varactor (also called a variable capacitance diode or varicap) D15 (D16, D25, D26). The anode of the varactor D15 (D16, D25, D26) is connected to the source follower output, and the cathode is connected to the output of the parallel circuit of the capacitor C11 (C12, C21, C22) and resistor R12 (R13, R22, R23) (that is, to the drain of the transistor T11 (T12, T21, T22)).

Here, in the first master-circuit load section (and similarly in the second master-circuit load section and the first and second slave-circuit load sections), since the potential across the resistor R14 is constant regardless of the frequency, the anode potential of the varactor D15 is also constant, but the cathode potential of the varactor D15 varies with the frequency because the output of the parallel circuit of the capacitor C11 and resistor R12 is small in the high frequency range and large in the low frequency range. That is, in the high frequency range, the potential difference between the two terminals of the varactor D15 is small, but in the low frequency range, the potential difference between the two terminals of the varactor D15 is large.

As a result, the capacitance of the varactor D15 is small in the high frequency range and large in the low frequency range. That is, in the frequency dividing circuit of the fourth embodiment, the load capacitance also changes with frequency. According to the frequency dividing circuit of the fourth embodiment, since, in the low frequency range, the effect of the increased load capacitance works in conjunction with the previously described effect of the increased load resistance, the time constant becomes longer than that in the first to third embodiments, and the operation at lower frequencies thus becomes possible.

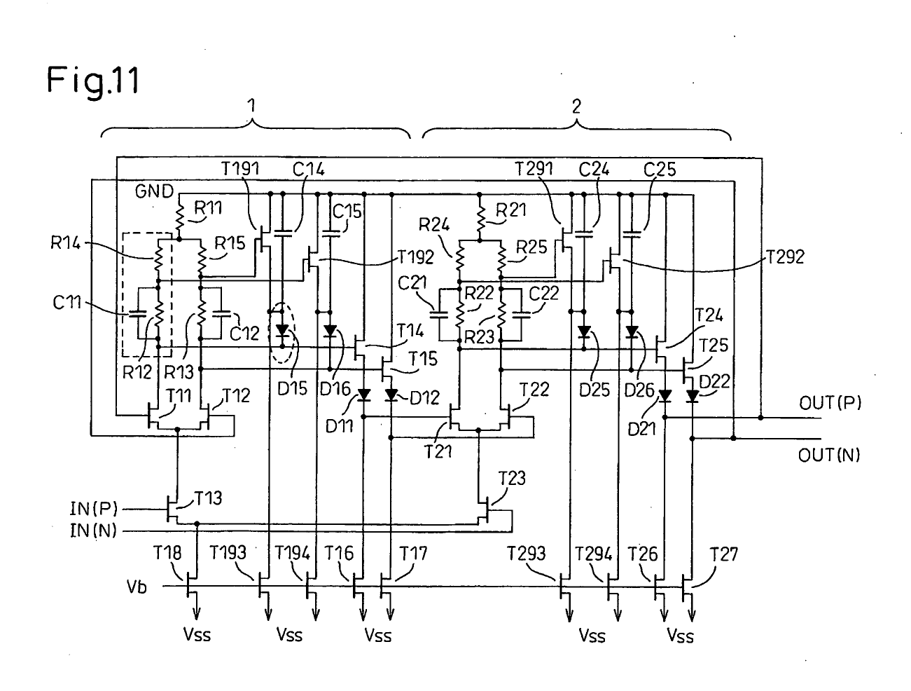

FIG. 11 is a circuit diagram showing a frequency dividing circuit according to a fifth embodiment.

As is apparent from a comparison between FIG. 11 and the above described FIG. 10, the frequency dividing circuit of the fifth embodiment is configured so that the potential developed across the resistor R14 (R24) is received by the source follower circuit formed from the transistor T192 (T292), not by the transistor T191 (T291), and so that the potential developed across the resistor R15 (R25) is received by the source follower circuit formed from the transistor T191 (T291), not by the transistor T192 (T292). That is, the cathodes of the varactors D15 and D16 (D25 and D26) are each connected to the differential input side of the other.

With this arrangement, the change of the voltage across each of the varactors D15, D16, D25, and D26 becomes greater than in the fourth embodiment and, as a result, the time constant in the low frequency range becomes even longer, making it possible to perform the frequency dividing operation at lower frequencies.

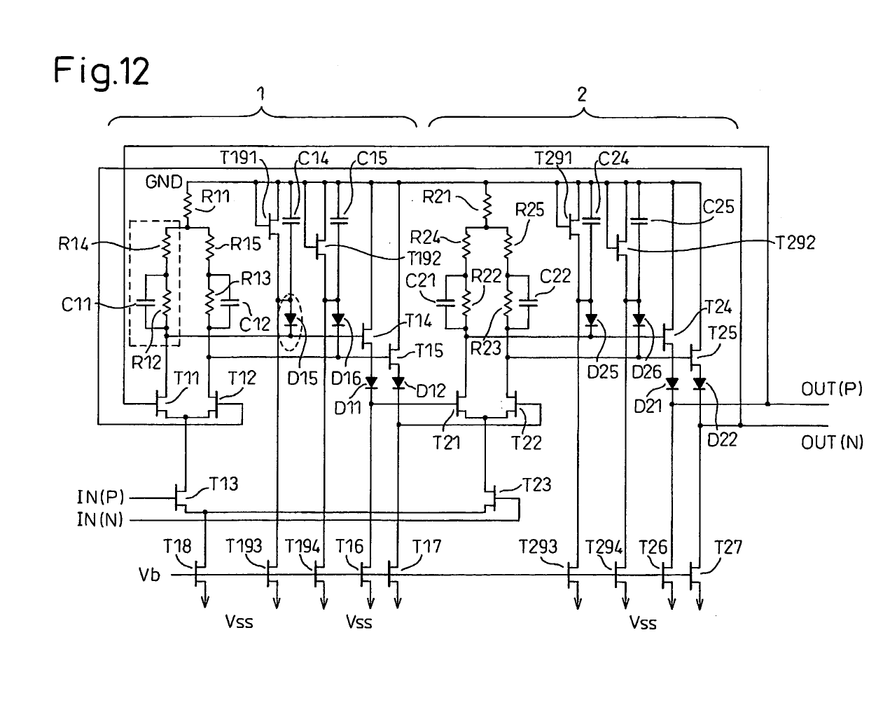

FIG. 12 is a circuit diagram showing a frequency dividing circuit according to a sixth embodiment.

As is apparent from a comparison between FIG. 12 and the earlier described FIG. 10, the frequency dividing circuit of the sixth embodiment differs in that the gates of the source follower transistors T191, T192, T291, and T292 are connected to the high potential power supply line (GND).

More specifically, the master circuit 1 comprises the fifth and sixth transistors T191 and T192 whose gate and drain terminals are connected to the first power supply line (the high potential power supply line GND) and the first and second master-circuit varactors D15 and D16 connected between the sources of the fifth and sixth transistors T191 and T192 and the drains of the differential pair transistors T11 and T12, respectively, in the master circuit 1; likewise, the slave circuit 2 comprises the seventh and eighth transistors T291 and T292 whose gate and drain terminals are connected to the first power supply line (GND) and the first and second slave-circuit varactors D25 and D26 connected between the sources of the seventh and eighth transistors T291 and T292 and the drains of the differential pair transistors T21 and T22, respectively, in the slave circuit 2.

In this circuit configuration also, the operation at lower frequencies can be achieved by using the capacitances of the varactors D15, D16, D25, and D26.

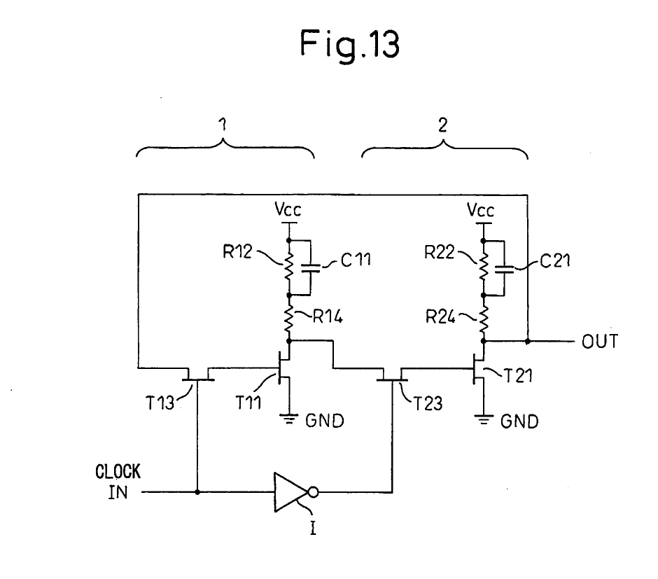

FIG. 13 is a circuit diagram showing a frequency dividing circuit according to a seventh embodiment.

As shown in FIG. 13, the frequency dividing circuit of the seventh embodiment has a single-ended configuration in which the master circuit 1 comprises transistors T11 and T13, resistors R12 and R14, and a capacitor C11, and the slave circuit 2 comprises transistors T21 and T23, resistors R22 and R24, and a capacitor C21. An inverter I is provided to invert an single-ended input clock IN and to apply it to the gate of the transistor T23.

In the frequency dividing circuit of the seventh embodiment, Vcc is the high potential power supply (for example, +1.6 volts) and GND is the low potential power supply (for example, 0 volt). Further, in the master-circuit load section of the master circuit 1, the parallel circuit of the resistor R21 and capacitor C11 is connected, for example, to the high potential power supply Vcc, and the resistor R14 is connected to the drain of the transistor T11, but it will be appreciated that the connection may be reversed, for example, as previously shown in FIG. 5.

In this way, the embodiment can be applied not only to a frequency dividing circuit of a differential configuration but also to a frequency dividing circuit of a single-ended configuration.

As described in detail above, according to the embodiments, a dynamic frequency dividing circuit can be provided that achieves a reduction in the circuit size because of the elimination of the need for a special switching circuit or control circuit, and that achieves a wide operating frequency range while reducing the power consumption by eliminating the need for a circuit such as a positive feedback circuit that consumes extra power. More specifically, when a simple divide-by-two frequency dividing circuit is taken as an example, since the switching circuit and control circuit occupy approximately the same area as the core portion of the frequency dividing circuit, the embodiments can reduce the circuit size by more than 50% compared, for example, with the prior art frequency dividing circuit of FIG. 3 that aims at extending the operating frequency range by switching the load between different values.

According to the embodiments, a frequency dividing circuit can be provided that has a wide operating frequency range, and that achieves compact size and low power consumption by eliminating the need for a special switching circuit or control circuit.

The embodiments can be applied widely as a frequency dividing circuit that generates a signal whose frequency is an integral submultiple of the input signal frequency, for example, in a prescaler section of a frequency synthesizer IC for a radio communication system, in a clock generating section of an optical communication IC or in a π/2 phase shifter or the like.

Many different embodiments may be constructed without departing from the scope of the present invention, and it should be understood that the present invention is not limited to the specific embodiments described in this specification, except as defined in the appended claims.

What is claimed is:

1. A frequency dividing circuit having a master circuit and a slave circuit, wherein a load section in at least either one of said master and slave circuits is constructed to provide an impedance that decreases with increasing frequency.

2. The frequency dividing circuit as claimed in claim 1, wherein said load section comprises two load resistors connected in series between a first power supply line and a transistor to which an input signal is applied, and a capacitor connected in parallel with one of said two load capacitors.

3. The frequency dividing circuit as claimed in claim 2, wherein said series-connected two load resistors are chosen to provide a combined resistance whose value is suitable for operation in a low operating frequency range of said frequency dividing circuit, and the other one of said two load resistors that is not connected in parallel with said capacitor is chosen to provide a resistance whose value is suitable for operation in a high operating frequency range of said frequency dividing circuit.

4. The frequency dividing circuit as claimed in claim 1, wherein said load section is provided in each of said master and slave circuits, and the load section of said master circuit and the load section of said slave circuit are identical in configuration.

5. The frequency dividing circuit as claimed in claim 4, wherein:
said frequency dividing circuit is configured as a differential circuit; and
a differential output of said master circuit is input to a differential transistor pair in said slave circuit, while a differential output of said slave circuit is taken as an output of said frequency dividing circuit and, at the same time, is fed back to a differential transistor pair in said master circuit, and wherein:
the load section provided in said master circuit comprises a first master-circuit load section provided between a first power supply line and a first transistor forming said differential transistor pair in said master circuit, and a second master-circuit load section provided between said first power supply line and a second transistor forming said differential transistor pair in said master circuit; and
the load section provided in said slave circuit comprises a first slave-circuit load section provided between said first power supply line and a third transistor forming said differential transistor pair in said slave circuit, and a second slave-circuit load section provided between said first power supply line and a fourth transistor forming said differential transistor pair in said slave circuit.

6. The frequency dividing circuit as claimed in claim 5, wherein:
said first and second master-circuit load sections each comprise two master-circuit load resistors connected in series between said first or second transistor and said first power supply line, and a master-circuit load capacitor connected in parallel with one of said two master-circuit load resistors; and
said first and second slave-circuit load sections each comprise two slave-circuit load resistors connected in series between said third or fourth transistor and said first power supply line, and a slave-circuit load capacitor connected in parallel with one of said two slave-circuit load resistors.

7. The frequency dividing circuit as claimed in claim 6, wherein:
said series-connected two master-circuit load resistors and said series-connected two slave-circuit load resistors are respectively chosen to provide a combined resistance whose value is suitable for operation in a low operating frequency range of said frequency dividing circuit; and
the other one of said two master-circuit load resistors that is not connected in parallel with said master-circuit load capacitor and the other one of said two slave-circuit load resistors that is not connected in parallel with said slave-circuit load capacitor are each chosen to provide a resistance whose value is suitable for operation in a high operating frequency range of said frequency dividing circuit.

8. The frequency dividing circuit as claimed in claim 6, further comprising:
an additional master-circuit load capacitor provided between a node connecting said two master-circuit load resistors in said first master-circuit load section and a node connecting said two master-circuit load resistors in said second master-circuit load section; and
an additional slave-circuit load capacitor provided between a node connecting said two slave-circuit load resistors in said first slave-circuit load section and a node connecting said two slave-circuit load resistors in said second slave-circuit load section.

9. The frequency dividing circuit as claimed in claim 6, wherein said master-circuit load capacitor and said slave-circuit load capacitor are each formed from a diode.

10. The frequency dividing circuit as claimed in claim 9, wherein said diode is a varactor.

11. The frequency dividing circuit as claimed in claim 6, wherein:
said master circuit further comprises first and second master-circuit source follower circuits each of which receives a potential developed across the other one of said master-circuit load resistors that is not connected in parallel with said master-circuit load capacitor, and first and second master-circuit varactors to which outputs of said first and second master-circuit source follower circuits are respectively applied; and
said slave circuit further comprises first and second slave-circuit source follower circuits each of which receives a potential developed across the other one of said slave-circuit load resistors that is not connected in parallel with said slave-circuit load capacitor, and first and second slave-circuit varactors to which outputs of said first and second slave-circuit source follower circuits are respectively applied.

12. The frequency dividing circuit as claimed in claim 11, wherein:
said first master-circuit source follower circuit receives the potential developed across the other one of said master-circuit load resistors that is not connected in parallel with said master-circuit load capacitor in said first master-circuit load section, while said second master-circuit source follower circuit receives the potential developed across the other one of said master-circuit load resistors that is not connected in parallel with said master-circuit load capacitor in said second master-circuit load section; and
said first slave-circuit source follower circuit receives the potential developed across the other one of said slave-circuit load resistors that is not connected in parallel with said slave-circuit load capacitor in said first slave-circuit load section, while said second slave-circuit source follower circuit receives the potential developed across the other one of said slave-circuit load resistors that is not connected in parallel with said slave-circuit load capacitor in said second slave-circuit load section.

13. The frequency dividing circuit as claimed in claim 11, wherein:
said first master-circuit source follower circuit receives the potential developed across the other one of said master-circuit load resistors that is not connected in parallel with said master-circuit load capacitor in said second master-circuit load section, while said second master-circuit source follower circuit receives the potential developed across the other one of said master-circuit load resistors that is not connected in parallel with said master-circuit load capacitor in said first master-circuit load section; and
said first slave-circuit source follower circuit receives the potential developed across the other one of said slave-circuit load resistors that is not connected in parallel with said slave-circuit load capacitor in said second slave-circuit load section, while said second slave-circuit source follower circuit receives the potential developed across the other one of said slave-circuit load resistors that is not connected in parallel with said slave-circuit load capacitor in said first slave-circuit load section.

14. The frequency dividing circuit as claimed in claim 11, wherein:
said master circuit further comprises fifth and sixth transistors whose gate and drain terminals are connected to said first power supply line, and first and second master-circuit varactors connected between sources of said fifth and sixth transistors and drains of said differential pair transistors, respectively, in said master circuit; and
said slave circuit further comprises seventh and eighth transistors whose gate and drain terminals are connected to said first power supply line, and first and second slave-circuit varactors connected between sources of said seventh and eighth transistors and drains of said differential pair transistors, respectively, in said slave circuit.
